(19) United States
(12) Patent Application Publication
(10) Pub. No.: US 2025/0372373 A1
(43) Pub. Date: Dec. 4, 2025

(54) GATE-ALL-AROUND (GAA) INTERFACE MODIFICATIONS TO IMPROVE ABRUPTNESS

(71) Applicant: Applied Materials, Inc., Santa Clara, CA (US)

(72) Inventors: John TOLLE, Gilbert, AZ (US); Joe MARGETIS, Gilbert, AZ (US); Thomas KIRSCHENHEITER, Tempe, AZ (US); Shawn THOMAS, Chesterfield, MO (US)

(21) Appl. No.: 19/202,528

(22) Filed: May 8, 2025

Related U.S. Application Data
(60) Provisional application No. 63/655,303, filed on Jun. 3, 2024.

(51) Int. Cl. H01L 21/02; C23C 16/06; C23C 16/24; C23C 16/455; C30B 25/16; C30B 25/18; C30B 29/06; C30B 29/52; C30B 29/68

(52) U.S. Cl. CPC H01L 21/02579; C23C 16/06; C23C 16/24; C23C 16/45529; C23C 16/45553; C30B 25/165; C30B 25/186; C30B 29/06; C30B 29/52; C30B 29/68; H01L 21/02532; H01L 21/0262

(57) ABSTRACT

Superlattice structures that may be used in gate-all around (GAA) transistor devices and methods for manufacturing the same are provided. In one or more implementations of the present disclosure, carbon-containing precursors are used to dose the SiGe surface prior to silicon channel growth to suppress germanium diffusion. The carbon-containing precursors can be selected from organosilane precursors, organogermane precursors, and carbon precursors. The carbon-containing precursor can be used with chlorinated precursors. The carbon-containing precursor can be flowed throughout the growth of the entire SiGe thickness. The carbon-containing precursor can be flowed toward the end of the growth of the SiGe thickness. The carbon-containing precursor can be flowed after growth of the SiGe thickness.

### CROSS-REFERENCE TO RELATED APPLICATIONS

This application claims the benefit of U.S. Provisional Patent Application Ser. No. 63/655,303, filed Jun. 3, 2024, which is incorporated by reference herein in its entirety.

### TECHNICAL FIELD

The present disclosure relates to transistor devices and methods for manufacturing transistor devices. More particularly, the present disclosure relates to superlattice structures that may be used in gate-all around (GAA) transistor devices and methods for manufacturing the same.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thus improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). In a GAA device all side surfaces of the channel region are surrounded by the gate electrode, which allows for fuller depletion in the channel region and results in less short-channel effects due to a steeper sub-threshold current swing and smaller drain induced barrier lowering (DIBL).

As transistor dimensions are scaled down to smaller technology nodes, there is a need for further improvements in GAA design and manufacturing.

### SUMMARY

The present disclosure relates to transistor devices and methods for manufacturing transistor devices. More particularly, the present disclosure relates to superlattice structures that may be used in GAA transistor devices and methods for manufacturing the same.

In one aspect, a method of fabricating a film stack is provided. The method includes sequentially depositing a carbon-doped silicon germanium stack and a silicon film to form a carbon-doped silicon-germanium and silicon mini-stack disposed on a substrate during a deposition cycle. The method further includes repeating the deposition cycle to prepare a multi-layered epitaxial stack including two or more of the carbon-doped silicon-germanium and silicon mini-stacks on the substrate. The deposition cycle includes exposing a workpiece including the substrate to a first gas including a silicon precursor, a silicon-chlorine precursor, a germanium precursor, and a carrier gas to deposit a silicon-germanium layer, starting a flow of a carbon-containing precursor, exposing the workpiece to a second gas including the silicon precursor, the silicon-chlorine precursor, the carbon-containing precursor, the germanium precursor, and the carrier gas to deposit a carbon-silicon-germanium layer on the silicon-germanium layer, ceasing the flow of the carbon-containing precursor and the germanium precursor, exposing the workpiece to a third gas including the silicon precursor, the silicon-chlorine precursor, and the carrier gas to deposit a silicon seed layer on the carbon silicon-germanium layer, ceasing a flow of the silicon-chlorine precursor, and exposing the workpiece to a fourth gas including the silicon precursor and the carrier gas to deposit a silicon bulk layer on the silicon seed layer.

Implementations may include one or more of the following. The carbon-containing precursor is selected from silicon-carbon precursors, germanium-carbon precursors, carbon precursors, or a combination thereof. The carbon-containing precursor is selected from methylsilane, dimethylsilane, ethylsilane, diethylsilane, methyldisilane, dimethyldisilane, hexamethyldisilane, or a combination thereof. The carbon-containing precursor is selected from methylgermane, dimethylgermane, ethylgermane, diethylgermane, methyldigermane, dimethyldigermane, hexamethyldigermane ((CH₃)₆Ge₂), or a combination thereof. The carbon-containing precursor is selected from methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), or a combination thereof. The deposition cycle is repeated from two times to five times to prepare the multi-layered epitaxial stack. The silicon precursor includes silane, disilane, trisilane, tetrasilane, or any combination thereof. The silicon-chlorine precursor includes monochlorosilane, dichlorosilane, trichlorosilane, tetracholorosilane, hexachlorodisilane, or any combination thereof. The carbon-containing precursor includes one or more alkylsilanes. The carbon-containing precursor includes methylsilane, dimethylsilane, or any combination thereof. The germanium precursor includes germane. The carrier gas includes hydrogen (H₂), nitrogen (N₂), argon, helium, or any combination thereof. The carrier gas includes hydrogen (H₂) and nitrogen (N₂) having a hydrogen to nitrogen molar ratio in a range from about 1:10 to about 10:1. The substrate includes silicon, a silicon germanium compound, or a dopant thereof. The carbon-doped silicon germanium stack has a thickness in a range from about 5 nm to about 20 nm. The silicon-germanium layer has a thickness in a range from about 1 nm to about 10 nm. The carbon-silicon-germanium layer has a thickness in a range from about 1 nm to about 20 nm. The silicon-germanium layer includes about 10 at % to about 30 at % of germanium and about 70 at % to about 90 at % of silicon. The carbon-silicon-germanium layer includes about 70 at % to about 90 at % of silicon, about 10 at % to about 30 at % of germanium, and about 0.2 at % to about 3 at % of carbon. The silicon film has a thickness in a range from about 10 nm to about 150 nm. The silicon seed layer has a thickness in a range from about 0.1 nm to about 1 nm. The silicon bulk layer has a thickness in a range from about 10 nm to about 150 nm. A gate-all-around transistor is formed from the substrate and the multi-layered epitaxial stack. The carbon-doped silicon-germanium and the silicon mini-stack are a portion of a memory device. The memory device is a 3D-DRAM (three-dimensional, dynamic random access memory) device.

In another aspect, a workpiece is provided. The workpiece includes a multi-layered epitaxial stack disposed on a substrate. The multi-layered epitaxial stack includes a plurality of carbon-doped silicon-germanium and silicon mini-stacks. Each of the carbon-doped silicon-germanium and silicon mini-stacks includes a carbon-doped silicon germanium stack and a silicon film. The carbon-doped silicon germanium stack includes a carbon-silicon-germanium layer disposed on a silicon-germanium layer and the silicon film includes a silicon bulk layer disposed on a silicon seed layer.

Implementations may include one or more of the following. The carbon-doped silicon germanium stack includes the carbon-silicon-germanium layer disposed on the silicon-germanium layer, and wherein the silicon film includes the silicon bulk layer on the silicon seed layer. The multi-layered epitaxial stack contains a plurality of carbon-doped silicon-germanium and silicon mini-stacks containing about two stacks to about five stacks. The multi-layered epitaxial stack contains a plurality of carbon-doped silicon-germanium and silicon mini-stacks containing about 30 stacks to about 100 stacks. The substrate includes silicon, a silicon germanium compound, or a dopant thereof. The carbon-doped silicon germanium stack has a thickness in a range from about 5 nm to about 20 nm. The silicon-germanium layer has a thickness in a range from about 1 nm to about 10 nm. The carbon-silicon-germanium layer has a thickness in a range from about 1 nm to about 20 nm. Each of the silicon-germanium layer includes about 10 at % to about 30 at % of germanium and about 70 at % to about 90 at % of silicon. The carbon-silicon-germanium layer includes about 70 at % to about 90 at % of silicon, about 10 at % to about 30 at % of germanium, and about 0.2 at % to about 3 at % of carbon. The silicon film has a thickness in a range from about 10 nm to about 150 nm. The silicon seed layer has a thickness in a range from about 0.1 nm to about 1 nm. The silicon bulk layer has a thickness in a range from about 10 nm to about 150 nm. The carbon-doped silicon-germanium and silicon mini-stack is a portion of a memory device. The memory device is a 3D-DRAM (three-dimensional, dynamic random access memory) device. The substrate and the multi-layered epitaxial stack are part of a gate-all-around transistor.

In yet another implementation, a processing system is provided. The processing system includes a processing chamber and a system controller. The system controller is configured to cause the processing system to sequentially depositing a carbon-doped silicon germanium stack and a silicon film to form a carbon-doped silicon-germanium and silicon mini-stack disposed on a substrate during a deposition cycle and repeating the deposition cycle to prepare a multi-layered epitaxial stack including two or more of the carbon-doped silicon-germanium and silicon mini-stacks on the substrate. The deposition cycle includes exposing a workpiece including the substrate to a first gas including a silicon precursor, a silicon-chlorine precursor, a germanium precursor, and a carrier gas to deposit a silicon-germanium layer, starting a flow of a carbon-containing precursor, exposing the workpiece to a second gas including the silicon precursor, the silicon-chlorine precursor, the carbon-containing precursor, the germanium precursor, and the carrier gas to deposit a carbon-silicon-germanium layer on the silicon-germanium layer, ceasing the flow of the carbon-containing precursor and the germanium precursor, exposing the workpiece to a third gas including the silicon precursor, the silicon-chlorine precursor, and the carrier gas to deposit a silicon seed layer on the carbon silicon-germanium layer, ceasing a flow of the silicon-chlorine precursor, and exposing the workpiece to a fourth gas including the silicon precursor and the carrier gas to deposit a silicon bulk layer on the silicon seed layer.

Implementations may include one or more of the following. The carbon-containing precursor is selected from silicon-carbon precursors, germanium-carbon precursors, carbon precursors, or a combination thereof. The carbon-containing precursor is selected from methylsilane, dimethylsilane, ethylsilane, diethylsilane, methyldisilane, dimethyldisilane, hexamethyldisilane, or a combination thereof. The carbon-containing precursor is selected from methylgermane, dimethylgermane, ethylgermane, diethylgermane, methyldigermane, dimethyldigermane, hexamethyldigermane ((CH₃)₆Ge₂), or a combination thereof. The carbon-containing precursor is selected from methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), or a combination thereof. The deposition cycle is repeated from two times to five times to prepare the multi-layered epitaxial stack. The silicon precursor includes silane, disilane, trisilane, tetrasilane, or any combination thereof. The silicon-chlorine precursor includes monochlorosilane, dichlorosilane, trichlorosilane, tetracholorosilane, hexachlorodisilane, or any combination thereof. The carbon-containing precursor includes one or more alkylsilanes. The carbon-containing precursor includes methylsilane, dimethylsilane, or any combination thereof. The germanium precursor includes germane. The carrier gas includes hydrogen (H₂), nitrogen (N₂), argon, helium, or any combination thereof. The carrier gas includes hydrogen (H₂) and nitrogen (N₂) having a hydrogen to nitrogen molar ratio in a range from about 1:10 to about 10:1. The substrate includes silicon, a silicon germanium compound, or a dopant thereof. The carbon-doped silicon germanium stack has a thickness in a range from about 5 nm to about 20 nm. The silicon-germanium layer has a thickness in a range from about 1 nm to about 10 nm. The carbon-silicon-germanium layer has a thickness in a range from about 1 nm to about 20 nm. The silicon-germanium layer includes about 10 at % to about 30 at % of germanium and about 70 at % to about 90 at % of silicon. The carbon-silicon-germanium layer includes about 70 at % to about 90 at % of silicon, about 10 at % to about 30 at % of germanium, and about 0.2 at % to about 3 at % of carbon. The silicon film has a thickness in a range from about 10 nm to about 150 nm. The silicon seed layer has a thickness in a range from about 0.1 nm to about 1 nm. The silicon bulk layer has a thickness in a range from about 10 nm to about 150 nm. A gate-all-around transistor is formed from the substrate and the multi-layered epitaxial stack. The carbon-doped silicon-germanium and the silicon mini-stack are a portion of a memory device. The memory device is a 3D-DRAM (three-dimensional, dynamic random access memory) device.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, and may admit to other equally effective implementations.

FIG. 1 illustrates a schematic side view of one example of a deposition chamber in accordance with one or more implementations of the present disclosure.

FIG. 2 depicts a workpiece containing a multi-layered epitaxial stack disposed on a substrate, according to one or more implementations described and discussed herein.

FIG. 3 is a flowchart depicting a method for fabricating a multi-layered epitaxial stack, according to one or more implementations described and discussed herein.

FIG. 4 is a flowchart depicting a method for fabricating a transistor device incorporating a multi-layered epitaxial stack, according to one or more implementations described and discussed herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

The present disclosure relates to transistor devices and methods for manufacturing transistor devices. More particularly, the present disclosure relates to superlattice structures that may be used in gate-all around (GAA) transistor devices and methods for manufacturing the same.

Scaling down of silicon metal oxide semiconductor (MOS) devices has become a major challenge in the semiconductor industry. One problem with the scaling of conventional planar devices are the short channel effects, which start to dominate over device performance. One solution for this problem came with the introduction of multi-gate devices with three-dimensional architecture, such as fin based semiconductor devices or FINFETs and GAA devices. Due to their three-dimensional architecture with either the gate being wrapped around a thin semiconductor fin for FINFET or the gate electrode surrounding all side surfaces of the channel region for GAA, improved gate control (and thus less short channel effects) over the channel could be achieved by using multiple gates.

Superlattice structures may be utilized in the fabrication of devices with three-dimensional architecture. These superlattice structures incorporate films, for example, stacks of alternating silicon (Si) layers and silicon germanium (SiGe) layers, which possess varying characteristics depending upon the particular application for which the film is being deposited. SiGe layer/Si layer stacks often suffer from germanium diffusion into the silicon channel, which can adversely affect device performance. Current processes use chlorinated precursors to suppress diffusion of germanium into the silicon channel. Although chlorinated precursors are effective in suppressing the majority of the germanium diffusion, it is desirable suppress germanium diffusion even further close to Secondary Ion Mass Spectrometry (SIMS) detection levels.

In one or more implementations of the present disclosure, carbon-containing precursors are used to dose the SiGe surface prior to silicon channel growth to suppress germanium diffusion. The carbon-containing precursors can be selected from organosilane precursors, organogermane precursors, and carbon precursors. Organosilane precursors such as methylgermane, dimethylsilane, diethylsilane, etc. can be used to provide the carbon at the surface. Organogermane precursors such as methylgermane, dimethylgermane, diethylgermane, etc. can be used to provide the carbon at the surface. Carbon-only containing precursors such as methane, ethane, acetylene, etc. can be used to provide the carbon at the surface. The carbon-containing precursor can be used with chlorinated precursors. The carbon-containing precursor can be flowed throughout the growth of the entire SiGe thickness. The carbon-containing precursor can be flowed toward the end of the growth of the SiGe thickness. The carbon-containing precursor can be flowed after growth of the SiGe thickness.

In one or more implementations of the present disclosure, the method includes SiGe growth, exposure of the surface to the carbon-containing precursor, and silicon channel growth. In one or more other implementations of the present disclosure, the method includes SiGe growth, exposure of the surface to the carbon-containing precursor and a chlorinated precursor, and silicon channel growth. In one or more other implementations of the present disclosure, the method includes SiGe growth, exposure of the surface to the carbon-containing precursor, exposure of the surface to the chlorinated precursor, and silicon channel growth.

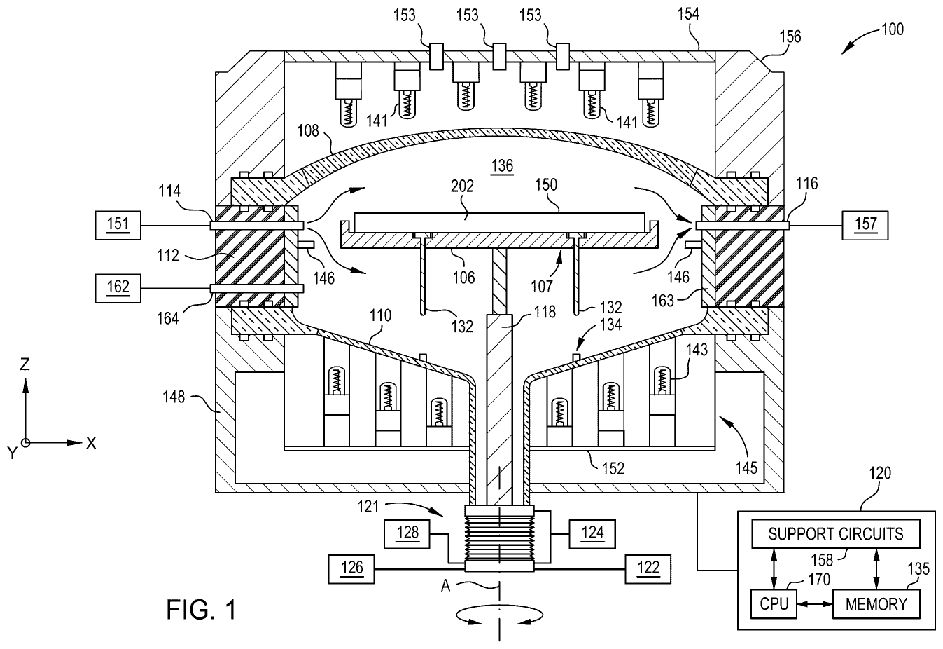

FIG. 1 is a schematic illustration of a type of deposition chamber 100 according to one implementation of the present disclosure. The deposition chamber 100 is utilized to grow an epitaxial film on a substrate, such as the substrate 202. The deposition chamber 100 may be used to perform the methods described herein, for example, the method 300. The deposition chamber 100 creates a cross-flow of precursors across the top surface 150 of the substrate 202.

The deposition chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper dome 108, a lower dome 110, a plurality of upper lamps 141, and a plurality of lower lamps 143. The substrate support 106 is disposed between the upper dome 108 and the lower dome 110. The plurality of upper lamps 141 are disposed between the upper dome 108 and a lid 154. The lid 154 includes a plurality of sensors 153 disposed therein for measuring the temperature within the deposition chamber 100. The plurality of lower lamps 143 are disposed between the lower dome 110 and a floor 152. The plurality of lower lamps 143 form a lower lamp assembly 145.

A processing region 136 is formed between the upper dome 108 and the lower dome 110. The processing region 136 has the substrate support 106 disposed therein. The substrate support 106 includes a top surface on which the substrate 202 is disposed. The substrate support 106 is attached to a shaft 118. The shaft 118 is connected to a motion assembly 121. The motion assembly 121 includes one or more actuators and/or adjustment devices that provide movement and/or adjustment of the shaft 118 and/or the substrate support 106 within the processing region 136. The motion assembly 121 includes a rotary actuator 122 that rotates the shaft 118 and/or the substrate support 106 about a longitudinal axis A of the deposition chamber 100. The motion assembly 121 further includes a vertical actuator 124 to lift and lower the substrate support 106 in the z-direction. The motion assembly 121 includes a tilt adjustment device 126 that is used to adjust the planar orientation of the substrate support 106 and a lateral adjustment device 128 that is used to adjust the position of the shaft 118 and the substrate support 106 side to side within the processing region 136.

The substrate support 106 may include lift pin holes 107 disposed therein. The lift pin holes 107 are sized to accommodate a lift pin 132 for lifting of the substrate 202 from the substrate support 106 either before or after a deposition process is performed. The lift pins 132 may rest on lift pin stops 134 when the substrate support 106 is lowered from a processing position to a transfer position.

The flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas parallel to the top surface 150 of a substrate 202 disposed within the processing region 136. The process gas inlets 114 are fluidly connected to a process gas source 151. The purge gas inlets 164 are fluidly connected to a purge gas source 162. The one or more exhaust gas outlets 116 are fluidly connected to an exhaust pump 157. Each of the process gas source 151 and the purge gas source 162 may be configured to supply one or more precursors or process gases into the processing region 136.

The deposition chamber 100 further includes a controller 120. The controller 120 can include a central processing unit (CPU) 170, memory 135, and support circuits (or I/O) (not shown). The CPU 170 may be one of any form of computer processors that are used in industrial settings for controlling various processing and hardware (e.g., process gas delivery, purge gas delivery, and other hardware) and monitor the processes (e.g., processing time, susceptor and/or substrate position, power to the lamp assemblies). The memory 135 is connected to the CPU 170, and may be one or more of readily available memory, such as random access memory (RAM), read only memory (ROM), floppy disk, hard disk, or any other form of digital storage, local or remote. Software instructions and data can be coded and stored within the memory 135 for instructing the CPU 170. The support circuits 158 are also connected to the CPU 170 for supporting the processor in a conventional manner. The support circuits 158 may include conventional cache, power supplies, clock circuits, input/out circuitry, subsystems, and the like. A program (or computer instructions) readable by the controller 120 determines which tasks are performable. The program may be software readable by the controller 120 and may include code to monitor and control (e.g., switch between), for example, the various gas sources (phosphorous-containing source gas, the one or more deposition gases, the n-type dopant gas). The controller 120 may be used to provide instructions to the deposition chamber 100 to perform the methods described herein, for example, the method 300. The controller 120 may be programmed or trained using machine learning algorithms based on data of the trend in carbon doping across previous batches. The controller 120 may use this historic data to either increase or decrease the amount of carbon dopant supplied during the deposition process.

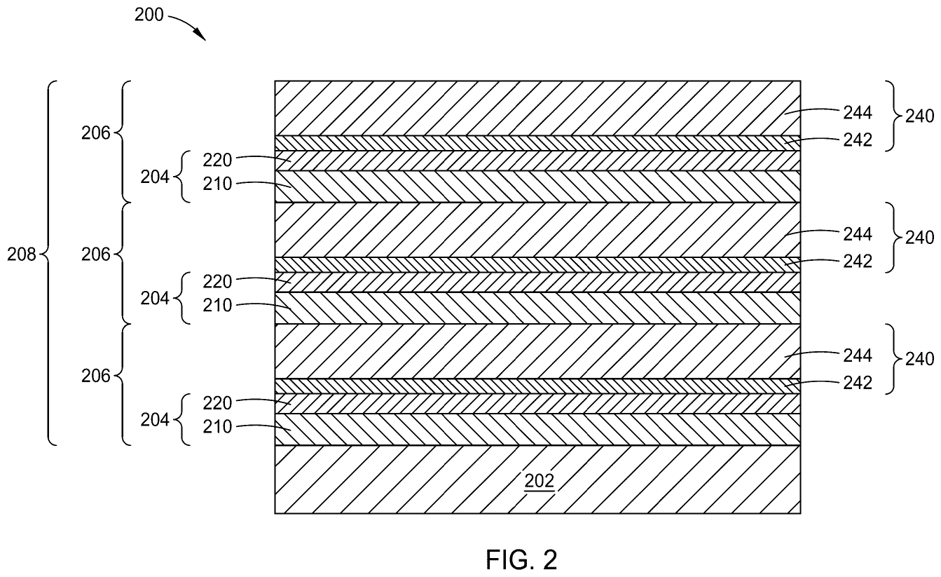

FIG. 2 depicts a workpiece 200 containing a multi-layered epitaxial stack 208 disposed on a substrate 202, according to one or more implementations described and discussed herein. The multi-layered epitaxial stack 208 contains a plurality or two, three, or more of carbon-doped silicon-germanium and silicon mini-stacks 206. Each of the carbon-doped silicon-germanium and silicon mini-stacks 206 contains a carbon-doped silicon germanium stack 204 and a silicon film 240. Typically, the silicon film 240 is disposed on the carbon-doped silicon germanium stack 204, however their order can be reversed such that the carbon-doped silicon germanium stack 204 is disposed on the silicon film 240.

In some implementations, the substrate 202 may be or include a bulk semiconductor substrate, a semiconductor-on-insulator (SOI) substrate, or the like. The term bulk semiconductor substrate refers to a substrate in which the entirety of the substrate is comprised of a semiconductor material. The bulk semiconductor substrate includes any suitable semiconducting material and/or combinations of semiconducting materials for forming a semiconductor structure. For example, the semiconducting layer may comprise one or more materials such as crystalline silicon (e.g., Si (100), Si (110), or Si (111)), silicon oxide, strained silicon, silicon germanium, doped or undoped polysilicon, doped or undoped silicon substrates, patterned or non-patterned substrates, doped silicon, germanium, gallium arsenide, or other suitable semiconducting materials. In some implementations, the semiconductor material is silicon. In other implementations, the semiconductor material is a doped material, such as n-doped silicon (n-Si), or p-doped silicon (p-Si). In some implementations, the substrate 202 includes additional materials, for example, silicide layers, metal silicide layers, semiconductor layers, etch stop layers (ESL), or metal layers.

The carbon-doped silicon germanium stack 204 contains a carbon-silicon-germanium layer 220 disposed on a silicon-germanium layer 210.

The silicon film 240 contains the silicon bulk layer 244 disposed on the silicon seed layer 242. In some implementations, the silicon seed layer 242 can be omitted and the silicon bulk layer 244 can be deposited directly on the carbon-silicon-germanium layer 220. Each of the silicon seed layer 242 and the silicon bulk layer 244 can independently contain one or more silicon materials, such as epitaxial silicon, crystalline silicon, any dopant thereof, or any combination thereof.

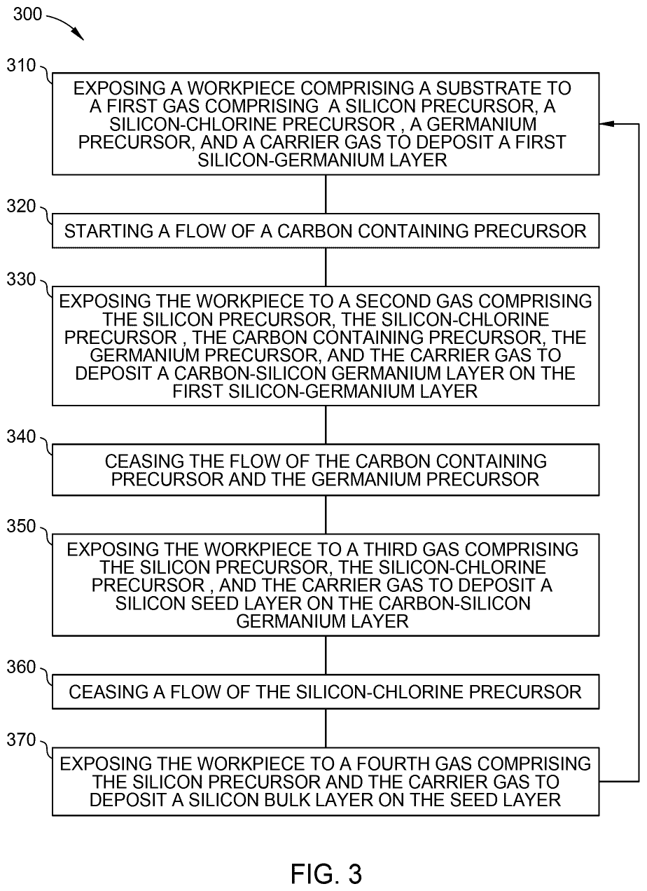

FIG. 3 is a flowchart depicting a process or method 300 for fabricating a multi-layered epitaxial stack, such as the multi-layered epitaxial stack 208 disposed on the substrate 202, according to one or more implementations described and discussed herein. Other multi-layered epitaxial stacks and various film stacks can be deposited, fabricated, or otherwise produced by the method 300. The method 300 may be part of a multi-operation fabrication process of a semiconductor device incorporating a superlattice structure, for example, a DRAM device or a gate-all-around (GAA) transistor device.

With reference to FIG. 2, a cross-sectional views of an implementation of a device structure for semiconductor devices is provided to illustrate the method 300 of FIG. 3. Although FIG. 2 is described in relation to the method 300, it will be appreciated that the structure disclosed in FIG. 2 is not limited to the method 300, but instead may stand alone as structures independent of the method 300. Similarly, although the method 300 is described in relation to FIG. 2, it will be appreciated that the method 300 is not limited to the structure disclosed in FIG. 2, but instead may stand alone independent of the structure disclosed in FIG. 2.

In one or more implementations, the method 300 is provided and includes sequentially depositing a carbon-doped silicon germanium stack 204 and a silicon film 240 to form a carbon-doped silicon-germanium and silicon mini-stack disposed on a substrate 202 during a deposition cycle. The method 300 includes repeating the deposition cycle to prepare a multi-layered epitaxial stack 208 containing two or more of the carbon-doped silicon-germanium and silicon mini-stacks 206 on the substrate 202.

At operation 310 of the method 300, the deposition cycle includes exposing the workpiece 200 containing the substrate 202 to a first gas containing a silicon precursor, a silicon-chlorine precursor, a germanium precursor, and a carrier gas to deposit a first silicon-germanium layer 210. The silicon precursor can be or contain one or more of silane, disilane, trisilane, tetrasilane, or any combination thereof. The silicon-chlorine precursor can be or contain one or more of monochlorosilane, dichlorosilane, trichlorosilane, tetracholorosilane, hexachlorodisilane, or any combination thereof. The germanium precursor can be or contain one or more of germane, tetrachlorogermane, one or more organogermane compounds, or any combination thereof. The carrier gas can be or contain one or more of hydrogen (H₂), nitrogen (N₂), argon, helium, or any combination thereof. In some examples, the carrier gas contains a mixture of hydrogen and nitrogen. The mixture of hydrogen and nitrogen can have a hydrogen to nitrogen molar ratio in a range from about 1:10 to about 10:1, about 1:5 to about 5:1, about 1:3 to about 3:1, about 1:2 to about 2:1, or about 1:1.

At operation 320 of the method 300, the deposition cycle includes starting a flow of one or more carbon-containing precursors. The one or more carbon-containing precursors can be used to provide the carbon at the surface of the silicon-germanium layer. The one or more carbon-containing precursors can include silicon-carbon precursors, germanium-carbon precursors, carbon precursors, or a combination thereof. The one or more carbon-containing precursors can include organosilanes, orgranogermanes, or a combination. The silicon-carbon precursor can be or include one or more alkylsilanes. In some examples, the silicon-carbon precursor can be or include methylsilane, dimethylsilane, or any combination thereof. Organosilane compounds include compounds with the empirical formula R_{y}SiₓH_{(2x+2-y)}, where R=methyl, ethyl, propyl or butyl, such as methylsilane (CH₃SiH₃), dimethylsilane ((CH₃)₂SiH₂), ethylsilane ((CH₃CH₂)SiH₃), diethylsilane ((C₂H₅)₂SiH₂), methyldisilane ((CH₃)Si₂H₅), dimethyldisilane ((CH₃)₂Si₂H₄) and hexamethyldisilane ((CH₃)₆Si₂). The germanium-carbon precursors can be or include one or more organogermanium compounds.

Organogermanium compounds include compounds with the empirical formula R_{y}GeₓH_{(2x+2-y)}, where R=methyl, ethyl, propyl or butyl, such as methylgermane (CH₃GeH₃), dimethylgermane ((CH₃)₂GeH₂), ethylgermane ((CH₃CH₂)GeH₃), diethylgermane ((C₂H₅)₂GeH₂), methyldigermane ((CH₃) Ge₂H₅), dimethyldigermane ((CH₃)₂Ge₂H₄) and hexamethyldigermane ((CH₃)₆Ge₂). The one or more carbon-containing precursors can include carbon precursors such as methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), isomers thereof, or a combination thereof.

Operation 310 and operation 320 may occur simultaneously, sequentially, partially overlap, or in any targeted order. For example, the flow of the carbon-containing precursor during operation 320 may occur simultaneously, sequentially, or partially overlap with the first gas of operation 310. In one implementation, at least two of the precursor gases are mixed prior to being delivered to the processing region. In another implementation, at least two of the precursor gases are delivered to the processing region separately and mixed within the processing region.

At operation 330 of the method 300, the deposition cycle includes exposing the workpiece 200 to a second gas containing the silicon precursor, the silicon-chlorine precursor, the carbon-containing precursor, the germanium precursor, and the carrier gas to deposit a carbon-silicon-germanium layer 220 on the first silicon-germanium layer 210. The carbon-silicon-germanium layer 220 suppresses or prevents diffusion of germanium from the first silicon-germanium layer 210 into the subsequently deposited silicon channel, which improves the compositional transition from the silicon germanium layer to the silicon layers.

At operation 340 of the method 300, the deposition cycle includes ceasing the flow of the carbon-containing precursor and the germanium precursor.

At operation 350 of the method 300, the deposition cycle includes exposing the workpiece 200 to a third gas containing the silicon precursor, the silicon-chlorine precursor, and the carrier gas to deposit a silicon seed layer 242 on the carbon-silicon-germanium layer 220.

At operation 360 of the method 300, the deposition cycle includes ceasing a flow of the silicon-chlorine precursor.

At operation 370 of the method 300, the deposition cycle includes exposing the workpiece 200 to a fourth gas containing the silicon precursor and the carrier gas to deposit a silicon bulk layer 244 on the silicon seed layer 242.

Operations 310-370 can be repeated as many times as preferred for preparing the multi-layered epitaxial stack 208 containing the targeted number of the carbon-doped silicon-germanium and silicon mini-stacks 206 on the substrate 202. The deposition cycle is repeated in a range from about 1, 2, 3, 4, 5, 6, 8, 10, about 12, about 15, about 20, about 25, about 30, about 40, or about 50 times to about 60, about 70, about 80, about 90, about 100, about 120, about 140, about 150, about 160, about 180, about 200, about 250, or more times to prepare the multi-layered epitaxial stack 208. For example, the deposition cycle can be repeated from about 2 times to about 250 times, about 2 times to about 5 times, about 5 times to about 200 times, about 10 times to about 200 times, about 20 times to about 200 times, about 30 times to about 200 times, about 40 times to about 200 times, about 50 times to about 200 times, about 80 times to about 200 times, about 100 times to about 200 times, about 120 times to about 200 times, about 150 times to about 200 times, about 180 times to about 200 times, about 5 times to about 100 times, about 10 times to about 100 times, about 20 times to about 100 times, about 30 times to about 100 times, about 40 times to about 100 times, about 50 times to about 100 times, about 60 times to about 100 times, about 80 times to about 100 times, or about 90 times to about 100 times to prepare the multi-layered epitaxial stack 208.

In one or more examples, the deposition cycle, including operations 310-370, can be repeated from about 3 times to about 200 times to prepare the multi-layered epitaxial stack 208. In other examples, the deposition cycle can be repeated from about 30 times to about 100 times to prepare the multi-layered epitaxial stack 208. In yet other examples, the deposition cycle can be repeated from about 3 times to about 5 times to prepare the multi-layered epitaxial stack 208. In some examples, the deposition cycle can be repeated from about 40 times to about 80 times to prepare the multi-layered epitaxial stack 208.

In one or more implementations, after completing operations 310-370 of the method 300, additional processes can be conducted, although not depicted in FIG. 3. For example, the method can include further exposing the workpiece 200 containing the multi-layered epitaxial stack 208 disposed on the substrate 202 to one or more annealing processes. The annealing processes can be or include a furnace anneal process, a spike anneal process, a rapid thermal anneal process, or any combination thereof.

In one or more examples, the annealing process is a furnace anneal process. The workpiece 200 is heated to a temperature of about 500° C. to about 750° C. for a period of about 5 hours to about 20 hours during the furnace anneal process.

In other examples, the annealing process is a spike anneal process. The workpiece 200 is heated to a temperature of about 1,050° C. for a period of about 1 second to about 100 seconds during the spike anneal process.

FIG. 2 depicts the workpiece 200 containing the multi-layered epitaxial stack 208 disposed on the substrate 202. The multi-layered epitaxial stack 208 can be a portion of a memory device. In one or more examples, the memory device is a 3D-DRAM (three-dimensional, dynamic random access memory) device. In one or more other examples, the memory device is a GAA transistor.

The substrate 202 can be or include any suitable substrate material. In one or more implementations, the substrate 202 contains one or more semiconductor materials and/or dopants, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, dopants thereof, or any combination thereof. Although a few examples of materials from which the substrate 202 may be formed are described herein, any material that may serve as a foundation upon which passive and active electronic devices (e.g., memories, transistors, capacitors, inductors, resistors, switches, integrated circuits, amplifiers, optoelectronic devices, or any other electronic devices) may be fabricated is within the spirit and scope of the present disclosure. In one or more examples, the substrate 202 can be or contain silicon, a silicon germanium compound, a silicon germanium carbon compound, or any dopant thereof.

The silicon-germanium layer 210 contains a silicon-germanium material which includes at least silicon and germanium. The silicon-germanium material can be doped or undoped. In one or more implementations, the silicon-germanium layer 210 contains a concentration of germanium in a range from about 5 atomic percent (at %), about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, the silicon-germanium layer 210 contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

In some implementations, the silicon-germanium layer 210 contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the silicon-germanium layer 210 and/or the silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

In one or more examples, the silicon-germanium layer 210 contains about 10 at % to about 30 at % of germanium and about 70 at % to about 90 at % of silicon. In other examples, the silicon-germanium layer 210 and/or the silicon-germanium material independently contains about 15 at % to about 25 at % of germanium and about 75 at % to about 85 at % of silicon.

In one or more implementations, the silicon-germanium layer 210 has a thickness in a range from about 0.5 nm, about 1 nm, about 2 nm, about 3 nm, about 4 nm, or about 5 nm to about 6 nm, about 7 nm, about 8 nm, about 9 nm, about 10 nm, about 12 nm, about 15 nm, or thicker. For example, the silicon-germanium layer 210 has a thickness of about 0.5 nm to about 15 nm, about 1 nm to about 10 nm, about 1 nm to about 8 nm, about 1 nm to about 8 nm, about 1 nm to about 5 nm, about 1 nm to about 4 nm, about 1 nm to about 3 nm, about 2 nm to about 10 nm, about 4 nm to about 10 nm, about 5 nm to about 10 nm, about 6 nm to about 10 nm, about 8 nm to about 10 nm, or about 10 nm to about 12 nm.

The carbon-silicon-germanium layer 220 contains carbon-silicon-germanium material which includes at least silicon, germanium, and carbon. The carbon-silicon-germanium material can be doped or undoped. In one or more implementations, each of the carbon-silicon-germanium layer 220 and/or the carbon-silicon-germanium material independently contains a concentration of germanium in a range from about 5 at %, about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the carbon-silicon-germanium layer 220 and/or the carbon-silicon-germanium material independently contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

Each of the carbon-silicon-germanium layer 220 and/or the carbon-silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the carbon-silicon-germanium layer 220 and/or the carbon-silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

Each of the carbon-silicon-germanium layer 220 and/or the carbon-silicon-germanium material independently contains a concentration of carbon in a range from about 0.1 at %, about 0.2 at %, about 0.3 at %, about 0.4 at %, about 0.5 at %, about 0.6 at %, about 0.8 at %, or about 1 at % to about 1.2 at %, about 1.5 at %, about 1.8 at %, about 2 at %, about 2.2 at %, about 2.5 at %, about 2.8 at %, about 3 at %, about 3.5 at %, about 4 at %, about 4.5 at %, or about 5 at %. For example, each of the carbon-silicon-germanium layer 220 and/or the carbon-silicon-germanium material independently contains about 0.1 at % to about 5 at %, about 0.2 at % to about 5 at %, about 0.2 at % to about 4 at %, about 0.2 at % to about 3.5 at %, about 0.2 at % to about 3 at %, about 0.2 at % to about 2.5 at %, about 0.2 at % to about 2 at %, about 0.2 at % to about 1.8 at %, about 0.2 at % to about 1.5 at %, about 0.2 at % to about 1.2 at %, about 0.2 at % to about 1 at %, about 0.2 at % to about 0.8 at %, about 0.2 at % to about 0.5 at %, about 0.5 at % to about 5 at %, about 0.5 at % to about 4 at %, about 0.5 at % to about 3.5 at %, about 0.5 at % to about 3 at %, about 0.5 at % to about 2.5 at %, about 0.5 at % to about 2 at %, about 0.5 at % to about 1.8 at %, about 0.5 at % to about 1.5 at %, about 0.5 at % to about 1.2 at %, about 0.5 at % to about 1 at %, about 0.5 at % to about 0.8 at %, about 1 at % to about 5 at %, about 1 at % to about 4 at %, about 1 at % to about 3.5 at %, about 1 at % to about 3 at %, about 1 at % to about 2.5 at %, about 1 at % to about 2 at %, about 1 at % to about 1.8 at %, about 1 at % to about 1.5 at %, about 1 at % to about 1.2 at % of carbon.

In one or more examples, each of the carbon-silicon-germanium layer 220 and/or the carbon-silicon-germanium material independently contains about 70 at % to about 90 at % of silicon, about 10 at % to about 30 at % of germanium, and about 0.2 at % to about 3 at % of carbon. In some examples, each of the carbon-silicon-germanium layer 220 and/or the carbon-silicon-germanium material independently contains about 75 at % to about 85 at % of silicon, about 15 at % to about 25 at % of germanium, and about 0.5 at % to about 1.5 at % of carbon. In other examples, each of the carbon-silicon-germanium layer 220 and/or the carbon-silicon-germanium material independently contains about 78 at % to about 82 at % of silicon, about 18 at % to about 22 at % of germanium, and about 0.8 at % to about 1.2 at % of carbon.

In one or more implementations, the carbon-silicon-germanium layer 220 has a thickness in a range from about 0.5 nm, about 1 nm, about 2 nm, about 3 nm, about 4 nm, about 5 nm, about 6 nm, about 8 nm, or about 10 nm to about 12 nm, about 14 nm, about 15 nm, about 16 nm, about 18 nm, about 20 nm, about 25 nm, or thicker. For example, the carbon-silicon-germanium layer 220 has a thickness of about 0.5 nm to about 25 nm, about 0.5 nm to about 20 nm, about 0.5 nm to about 15 nm, about 1 nm to about 25 nm, about 1 nm to about 20 nm, about 1 nm to about 15 nm, about 1 nm to about 10 nm, about 1 nm to about 8 nm, about 1 nm to about 8 nm, about 1 nm to about 5 nm, about 1 nm to about 4 nm, about 1 nm to about 3 nm, about 5 nm to about 25 nm, about 5 nm to about 20 nm, about 5 nm to about 15 nm, about 5 nm to about 10 nm, about 5 nm to about 8 nm, about 5 nm to about 8 nm, about 5 nm to about 7 nm, about 10 nm to about 25 nm, about 10 nm to about 20 nm, about 10 nm to about 15 nm, about 10 nm to about 12 nm, about 2 nm to about 10 nm, about 4 nm to about 10 nm, about 5 nm to about 10 nm, about 6 nm to about 10 nm, about 8 nm to about 10 nm, or about 10 nm to about 12 nm.

The carbon-doped silicon germanium stack 204 has a thickness in a range from about 1 nm, about 2 nm, about 3 nm, about 5 nm, about 6 nm, about 8 nm, or about 10 nm to about 12 nm, about 15 nm, about 18 nm, about 20 nm, about 25 nm, about 30 nm, about 40 nm, about 50 nm, or thicker. For example, the carbon-doped silicon germanium stack 204 has a thickness of about 1 nm to about 50 nm, about 5 nm to about 50 nm, about 5 nm to about 40 nm, about 5 nm to about 35 nm, about 5 nm to about 30 nm, about 5 nm to about 25 nm, about 5 nm to about 20 nm, about 5 nm to about 18 nm, about 5 nm to about 15 nm, about 5 nm to about 10 nm, about 5 nm to about 8 nm, about 10 nm to about 50 nm, about 10 nm to about 40 nm, about 10 nm to about 35 nm, about 10 nm to about 30 nm, about 10 nm to about 25 nm, about 10 nm to about 20 nm, about 10 nm to about 18 nm, about 10 nm to about 15 nm, about 10 nm to about 12 nm, about 15 nm to about 50 nm, about 15 nm to about 40 nm, about 15 nm to about 35 nm, about 15 nm to about 30 nm, about 15 nm to about 25 nm, about 15 nm to about 20 nm, or about 15 nm to about 18 nm.

The silicon seed layer 242 has a thickness in a range from about 0.05 nm, about 0.1 nm, about 0.2 nm, about 0.3 nm, about 0.4 nm, about 0.5 nm, about 0.6 nm, or to about 0.7 nm, about 0.8 nm, about 0.9 nm, about 1 nm, about 1.2 nm, about 1.5 nm, about 1.8 nm, about 2 nm, about 2.5 nm, about 3 nm, about 4 nm, about 5 nm, or thicker. For example, the silicon seed layer 242 has a thickness of about 0.05 nm to about 5 nm, about 0.05 nm to about 3 nm, about 0.05 nm to about 2 nm, about 0.05 nm to about 1 nm, about 0.05 nm to about 0.5 nm, about 0.1 nm to about 5 nm, about 0.1 nm to about 3 nm, about 0.1 nm to about 2 nm, about 0.1 nm to about 1 nm, about 0.1 nm to about 0.5 nm, about 0.5 nm to about 5 nm, about 0.5 nm to about 3 nm, about 0.5 nm to about 2 nm, or about 0.5 nm to about 1 nm.

The silicon bulk layer 244 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the silicon bulk layer 244 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

The silicon film 240 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the silicon film 240 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

FIG. 2 depicts the multi-layered epitaxial stack 208 containing three carbon-doped silicon-germanium and silicon mini-stacks 206 disposed on the substrate 202. However, the multi-layered epitaxial stack 208 may have a variety of different amounts of the carbon-doped silicon-germanium and silicon mini-stack 206 disposed on the substrate 202. The multi-layered epitaxial stack 208 may contain a range from 1 stack, 2 stacks, 3 stacks, 4 stacks, 5 stacks, 6 stacks, 7 stacks, 8 stacks, about 10 stacks, about 12 stacks, about 15 stacks, about 18 stacks, about 20 stacks, about 25 stacks, about 30 stacks, about 35 stacks, about 40 stacks, about 45 stacks, or about 50 stacks to about 55 stacks, about 60 stacks, about 70 stacks, about 80 stacks, about 90 stacks, about 100 stacks, about 110 stacks, about 120 stacks, about 130 stacks, about 140 stacks, about 150 stacks, about 160 stacks, about 170 stacks, about 180 stacks, about 190 stacks, about 200 stacks, about 220 stacks, about 250 stacks, about 300 stacks, or more of the carbon-doped silicon-germanium and silicon mini-stack 206. For example, the multi-layered epitaxial stack 208 may contain about 2 stacks to about 300 stacks, about 3 stacks to about 5 stacks, about 5 stacks to about 250 stacks, about 10 stacks to about 200 stacks, about 20 stacks to about 200 stacks, about 30 stacks to about 200 stacks, about 35 stacks to about 200 stacks, about 40 stacks to about 200 stacks, about 50 stacks to about 200 stacks, about 60 stacks to about 200 stacks, about 80 stacks to about 200 stacks, about 100 stacks to about 200 stacks, about 120 stacks to about 200 stacks, about 150 stacks to about 200 stacks, about 180 stacks to about 200 stacks, about 10 stacks to about 100 stacks, about 20 stacks to about 100 stacks, about 30 stacks to about 100 stacks, about 35 stacks to about 100 stacks, about 40 stacks to about 100 stacks, about 50 stacks to about 100 stacks, about 60 stacks to about 100 stacks, about 80 stacks to about 100 stacks, about 90 stacks to about 100 stacks, about 10 stacks to about 90 stacks, about 10 stacks to about 80 stacks, about 10 stacks to about 70 stacks, about 10 stacks to about 60 stacks, about 10 stacks to about 50 stacks, about 10 stacks to about 40 stacks, about 10 stacks to about 35 stacks, about 10 stacks to about 30 stacks, about 10 stacks to about 25 stacks, about 10 stacks to about 20 stacks, or about 10 stacks to about 15 stacks of the carbon-doped silicon-germanium and silicon mini-stack 206. In one or more examples, the multi-layered epitaxial stack 208 contains about 10 stacks to about 200 stacks of the plurality of carbon-doped silicon-germanium and silicon mini-stacks 206. In one or more examples, the multi-layered epitaxial stack 208 contains about 3 stacks to about 5 stacks of the plurality of carbon-doped silicon-germanium and silicon mini-stacks 206. In some examples, the multi-layered epitaxial stack 208 contains about 30 stacks to about 100 stacks of the plurality of carbon-doped silicon-germanium and silicon mini-stacks 206. In other examples, the multi-layered epitaxial stack 208 contains about 35 stacks to about 75 stacks of the plurality of carbon-doped silicon-germanium and silicon mini-stacks 206.

In some implementations, a method of fabricating a film stack is provided and includes sequentially depositing a carbon-doped silicon germanium stack 204 and a silicon film 240 to form a carbon-doped silicon-germanium and silicon mini-stack 206 disposed on a substrate 202 during a deposition cycle. The method also includes repeating the deposition cycle to prepare a multi-layered epitaxial stack 208 containing two or more of the carbon-doped silicon-germanium and silicon mini-stacks 206 on the substrate 202, where the deposition cycle is repeated from about 30 times to about 100 times to prepare the multi-layered epitaxial stack 208. The method further includes exposing the workpiece 200 containing the multi-layered epitaxial stack 208 disposed on the substrate 202 to an annealing process, where the annealing process is a furnace anneal process or a spike anneal process. The deposition cycle contains exposing a workpiece 200 containing the substrate 202 to a first gas containing a silicon precursor, a silicon-chlorine precursor, a germanium precursor, and a carrier gas to deposit a first silicon-germanium layer 210, starting a flow of a silicon-carbon precursor, and exposing the workpiece 200 to a second gas containing the silicon precursor, the silicon-chlorine precursor, the silicon-carbon precursor, the germanium precursor, and the carrier gas to deposit a carbon-silicon-germanium layer 220 on the first silicon-germanium layer 210. Optionally, the deposition cycle includes ceasing the flow of the silicon-carbon precursor and exposing the workpiece 200 to a third gas containing the silicon precursor, the silicon-chlorine precursor, the germanium precursor, and the carrier gas to deposit a second silicon-germanium layer (not shown) on the carbon-silicon-germanium layer 220. The deposition cycle further contains ceasing a flow of the germanium precursor and exposing the workpiece 200 to a fourth gas containing the silicon precursor, the silicon-chlorine precursor, and the carrier gas to deposit a silicon seed layer 242 on the second silicon-germanium layer. The deposition cycle further contains ceasing a flow of the silicon-chlorine precursor and exposing the workpiece 200 to a fifth gas containing the silicon precursor and the carrier gas to deposit a silicon bulk layer 244 on the silicon seed layer 242.

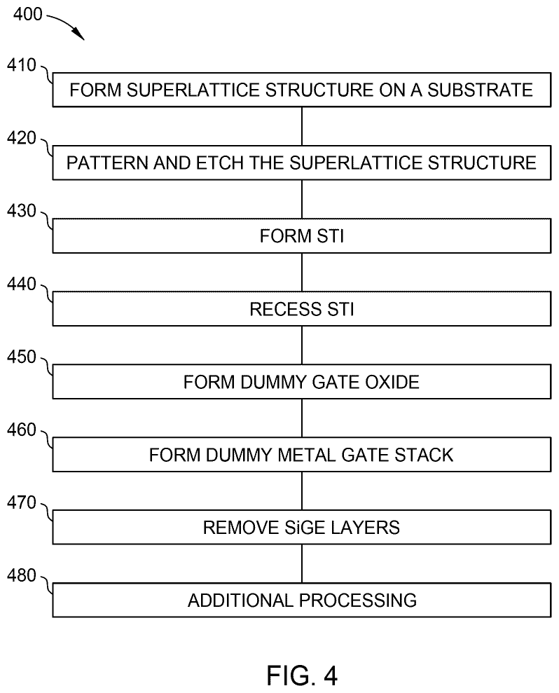

FIG. 4 is a flowchart depicting a method 400 for fabricating a transistor device incorporating a multi-layered epitaxial stack, according to one or more implementations described and discussed herein. At operation 410 of the method 400, a superlattice structure is formed on a substrate, for example, the multilayered epitaxial stack 208 formed on the substrate 202 as shown in FIG. 2. At operation 420, a patterning and etching process is performed to form trenches in the superlattice structure, after a hardmask layer is deposited on the top surface of the superlattice structure. In some implementations, photolithography techniques are utilized to pattern the hardmask layer. Generally, a photoresist material is deposited over the hardmask layer. The photoresist material is irradiated (exposed) with radiation, for example, light, through a patterned reticle in order to induce a reaction in the portions of the photoresist material exposed to the energy. The photoresist material is developed to remove a portion of the photoresist material, wherein the remaining photoresist material protects the underlying material from subsequent processing steps, such as etching. After the etching process of operation 420 is performed to the superlattice structure, remaining regions of the superlattice structure and the underlying substrate form fins.

At operation 430, shallow trench isolations (STIs) are formed, in accordance with some implementations. At operation 430 a deposition process may be performed to deposit a dielectric insulating material in the trenches between adjacent fins to form STIs. The STIs may be made of suitable dielectric materials such as silicon oxide, silicon nitride, silicon oxynitride, fluoride-doped silicate glass (FSG), low-k dielectrics such as carbon doped oxides, extremely low-k dielectrics such as porous carbon doped silicon dioxide, a polymer such as polyimide, combinations thereof, or the like. In some implementations, the deposition process of operation 430 is a process such as CVD, flowable CVD (FCVD), or a spin-on-glass process, although any acceptable process may be utilized. Subsequently, the STIs may be subject to one or more of a hardmask removal process and a process for removal of portions of the STIs extending over the top surfaces of the fins using, for example, an etch process, chemical mechanical polishing (CMP), or the like.

At operation 440, the sidewalls of the fins may be exposed by recessing of the STIs to form recessed STIs. In some implementations, the STIs are recessed using one or more selective etch processes utilizing the fins as an etch mask. For example, the STIs are recessed using one or more etching processes. A depth of the recessed STIs may be determined by a height of the multilayered epitaxial stack 208.

At operation 450, a dummy gate oxide layer may be formed over the exposed fins. In some implementations, the dummy gate oxide layer may be formed by a deposition process, for example, thermal oxidation, CVD, sputtering, or any other methods known and used in the art for forming a dummy gate oxide layer. In some implementations, the dummy gate oxide layer may be formed of a same material as the STIs. In other implementations, the dummy gate oxide layer may be made of one or more suitable dielectric materials such as silicon oxide, silicon nitride, low-k dielectrics such as carbon doped oxides, extremely low-k dielectrics such as porous carbon doped silicon dioxide, a polymer such as polyimide, the like, or a combination thereof. In other implementations, the dummy gate oxide layer includes dielectric materials having a high dielectric constant (k-value), for example, greater than 3.9. The materials may include silicon nitrides, oxynitrides, metal oxides such as HfO2, HfZrOx, HfSiOx, HfTiOx, HfAlOx, a combination thereof, multi-layers thereof, or the like.

At operation 460, a dummy metal layer may be deposited over the dummy gate oxide layer. In an implementation, the dummy metal layer is a conductive material and may be selected from a group comprising polycrystalline-silicon (poly-Si), poly-crystalline silicon-germanium (poly-SiGe), metallic nitrides, metallic silicides, metallic oxides, and metals. In an implementation, the dummy metal layer may be deposited by a deposition process, for example, PVD, CVD, sputter deposition, or other techniques known and used in the art for depositing conductive materials. Other materials, conductive and non-conductive, may be used. The top surface of the dummy metal layer may be planarized after it is deposited.

In some implementations, a hardmask may be patterned to form a dummy gate hardmask layer stack over the dummy metal layer. In particular implementations, a polysilicon etch and a dummy oxide removal process are performed using the dummy gate hardmask layer stack to pattern the dummy metal layer and the dummy gate oxide layer. During patterning, portions of the dummy metal layer and portions of the dummy gate oxide layer are removed from source/drain areas of the fins and portions of the dummy metal layer and portions of the dummy gate oxide layer remain over a channel region of the fins to form a dummy metal gate electrode. The dummy metal gate electrode may include the patterned dummy metal layer and the patterned dummy gate oxide layer disposed below the patterned dummy metal layer. The dummy metal gate electrode and the dummy gate hardmask layer stack collectively form a dummy metal gate stack (not shown).

The dummy metal gate stack may then be used to define and form source/drain regions from the exposed portions of fins. The dummy metal gate stack may then be removed to allow processing to be performed to define and form channel regions from the center portions of fins.

At operation 470, a removal process for the SiGe layers is performed. After removal of the first SiGe layers, the silicon layers remain in the fins. In particular implementations, the SiGe layer may be removed using an etchant that etches the silicon germanium at a higher rate than the silicon, such as NH₄OH:H₂O₂:H₂O (ammonia peroxide mixture, APM), H₂SO₄+H₂O₂ (sulfuric acid peroxide mixture, SPM), or the like. Other suitable processes and materials may be used. This etching process removes the SiGe layers. Thus, first nanowires or nanosheets are formed from the fins for an n-type device.

After operation 470, the semiconductor device structure may be subjected to additional processing at operation 480 to form the final device structure, for example, a GAA device.

The previously described implementations of the present disclosure have many advantages, including the following. The SiGe layers of the SiGe/Si superlattice structure may be formed using a carbon-containing precursor. These carbon-containing precursors provide for high growth rate with improved surface termination, which leads to reduced germanium diffusion and excellent interfacial abruptness. This interfacial abruptness provides improved etch selectivity between the SiGe and Si layers in the superlattice structure. The improved etch selectively widens the process window tuning, thus increasing adaptability and feasibility. However, the present disclosure does not entail that all the advantageous features and all the advantages need to be incorporated into every implementation of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A method of fabricating a film stack, comprising:
sequentially depositing a carbon-doped silicon germanium stack and a silicon film to form a carbon-doped silicon-germanium and silicon mini-stack disposed on a substrate during a deposition cycle; and
repeating the deposition cycle to prepare a multi-layered epitaxial stack comprising two or more of the carbon-doped silicon-germanium and silicon mini-stacks on the substrate, wherein the deposition cycle comprises:
exposing a workpiece comprising the substrate to a first gas comprising a silicon precursor, a silicon-chlorine precursor, a germanium precursor, and a carrier gas to deposit a silicon-germanium layer;
starting a flow of a carbon-containing precursor;
exposing the workpiece to a second gas comprising the silicon precursor, the silicon-chlorine precursor, the carbon-containing precursor, the germanium precursor, and the carrier gas to deposit a carbon-silicon-germanium layer on the silicon-germanium layer;
ceasing the flow of the carbon-containing precursor and the germanium precursor;
exposing the workpiece to a third gas comprising the silicon precursor, the silicon-chlorine precursor, and the carrier gas to deposit a silicon seed layer on the carbon silicon-germanium layer;
ceasing a flow of the silicon-chlorine precursor; and
exposing the workpiece to a fourth gas comprising the silicon precursor and the carrier gas to deposit a silicon bulk layer on the silicon seed layer.

2. The method of claim 1, wherein the carbon-containing precursor is selected from silicon-carbon precursors, germanium-carbon precursors, carbon precursors, or a combination thereof.

3. The method of claim 1, wherein the carbon-containing precursor is selected from methylsilane, dimethylsilane, ethylsilane, diethylsilane, methyldisilane, dimethyldisilane, hexamethyldisilane, or a combination thereof.

4. The method of claim 1, wherein the carbon-containing precursor is selected from methylgermane, dimethylgermane, ethylgermane, diethylgermane, methyldigermane, dimethyldigermane, hexamethyldigermane ((CH₃)₆Ge₂), or a combination thereof.

5. The method of claim 1, wherein the carbon-containing precursor is selected from methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), or a combination thereof.

6. The method of claim 1, wherein the deposition cycle is repeated from two times to five times to prepare the multi-layered epitaxial stack.

7. The method of claim 1, wherein the silicon precursor comprises silane, disilane, trisilane, tetrasilane, or any combination thereof.

8. The method of claim 1, wherein the silicon-chlorine precursor comprises monochlorosilane, dichlorosilane, trichlorosilane, tetracholorosilane, hexachlorodisilane, or any combination thereof.

9. The method of claim 1, wherein the carbon-containing precursor comprises one or more alkylsilanes.

10. A workpiece, comprising:
a multi-layered epitaxial stack disposed on a substrate, wherein:
the multi-layered epitaxial stack comprises a plurality of carbon-doped silicon-germanium and silicon mini-stacks;
each of the carbon-doped silicon-germanium and silicon mini-stacks comprises a carbon-doped silicon germanium stack and a silicon film;
the carbon-doped silicon germanium stack comprises a carbon-silicon-germanium layer disposed on a silicon-germanium layer; and
the silicon film comprises a silicon bulk layer disposed on a silicon seed layer.

11. The workpiece of claim 10, wherein the carbon-doped silicon germanium stack comprises the carbon-silicon-germanium layer disposed on the silicon-germanium layer, and wherein the silicon film comprises the silicon bulk layer on the silicon seed layer.

12. The workpiece of claim 10, wherein the multi-layered epitaxial stack contains a plurality of carbon-doped silicon-germanium and silicon mini-stacks containing about two stacks to about five stacks.

13. The workpiece of claim 10, wherein the multi-layered epitaxial stack contains a plurality of carbon-doped silicon-germanium and silicon mini-stacks containing about 30 stacks to about 100 stacks.

14. The workpiece of claim 10, wherein the substrate comprises silicon, a silicon germanium compound, or a dopant thereof.

15. The workpiece of claim 10, wherein the carbon-doped silicon germanium stack has a thickness in a range from about 5 nm to about 20 nm.

16. A processing system, comprising:
a processing chamber; and
a system controller configured to cause the processing system to:
sequentially depositing a carbon-doped silicon germanium stack and a silicon film to form a carbon-doped silicon-germanium and silicon mini-stack disposed on a substrate during a deposition cycle; and
repeating the deposition cycle to prepare a multi-layered epitaxial stack comprising two or more of the carbon-doped silicon-germanium and silicon mini-stacks on the substrate, wherein the deposition cycle comprises:
exposing a workpiece comprising the substrate to a first gas comprising a silicon precursor, a silicon-chlorine precursor, a germanium precursor, and a carrier gas to deposit a silicon-germanium layer;
starting a flow of a carbon-containing precursor;
exposing the workpiece to a second gas comprising the silicon precursor, the silicon-chlorine precursor, the carbon-containing precursor, the germanium precursor, and the carrier gas to deposit a carbon-silicon-germanium layer on the silicon-germanium layer;
ceasing the flow of the carbon-containing precursor and the germanium precursor;
exposing the workpiece to a third gas comprising the silicon precursor, the silicon-chlorine precursor, and the carrier gas to deposit a silicon seed layer on the carbon silicon-germanium layer;
ceasing a flow of the silicon-chlorine precursor; and
exposing the workpiece to a fourth gas comprising the silicon precursor and the carrier gas to deposit a silicon bulk layer on the silicon seed layer.

17. The processing system of claim 16, wherein the carbon-containing precursor is selected from silicon-carbon precursors, germanium-carbon precursors, carbon precursors, or a combination thereof.

18. The processing system of claim 16, wherein the carbon-containing precursor is selected from methylsilane, dimethylsilane, ethylsilane, diethylsilane, methyldisilane, dimethyldisilane, hexamethyldisilane, or a combination thereof.

19. The processing system of claim 16, wherein the carbon-containing precursor is selected from methylgermane, dimethylgermane, ethylgermane, diethylgermane, methyldigermane, dimethyldigermane, hexamethyldigermane ((CH₃)₆Ge₂), or a combination thereof.

20. The processing system of claim 16, wherein the carbon-containing precursor is selected from methane (CH₄), ethane (C₂H₆), acetylene (C₂H₂), ethylene (C₂H₄), propylene (C₃H₆), propane (C₃H₈), hexane (C₆H₁₄), benzene (C₆H₆), isoprene (C₅H₈), butadiene (C₄H₆), or a combination thereof.
